(19) United States
(12) Patent Application Publication
(10) Pub. No.: US 2012/0257339 A1
(43) Pub. Date: Oct. 11, 2012

(54) Multi-Channel Amplifier Techniques

(76) Inventors: Kent W. Leyde, Sammamish, WA (US); Tyler R. Hart, Seattle, WA (US); Khaled M. Boulos, Renton, WA (US); Jason A. Higgins, Seattle, WA (US)

(21) Appl. No.: 13/441,609

(22) Filed: Apr. 6, 2012

Related U.S. Application Data
(60) Provisional application No. 61/473,639, filed on Apr. 8, 2011.

(51) Int. Cl. H05K 7/00; H03F 3/45; H03F 3/68

(52) U.S. Cl. 361/679.01; 330/124 R; 330/69

(57) ABSTRACT

Techniques for amplifying a plurality of input voltages to generate a corresponding plurality of output voltages. In an exemplary embodiment, each of the plurality of input voltages is referenced to a common voltage comprising the average of the plurality of input voltages, without the need to reference an independently provided common voltage. In an alternative exemplary embodiment, techniques are provided for automatically measuring the input impedance between any two nodes corresponding to the plurality of input voltages. Further techniques are provided for coupling input nodes of the amplifier modules to a common reference voltage, and to the housing of the apparatus.

### CROSS REFERENCE TO RELATED APPLICATIONS

The present application claims the benefit of commonly owned U.S. Provisional Patent Application No. 61/473,639, filed Apr. 8, 2011, entitled “Multi-Channel Amplifier Techniques,” by Leyde et al., the complete disclosure of which is incorporated by reference herein in its entirety.

### INCORPORATION BY REFERENCE

All publications and patent applications mentioned in this specification are herein incorporated by reference to the same extent as if each individual publication or patent application was specifically and individually indicated to be incorporated by reference.

### TECHNICAL FIELD

The present disclosure relates generally to techniques for designing sensing devices that are implantable in a body of a patient.

### BACKGROUND

Implantable biomedical devices may utilize component microelectronic circuitry implanted in the body of a patient to perform functions benefiting the health of the patient. For example, in the field of neurological monitoring, multiple electrodes may be implanted in diverse locations near, on, or in a patient's brain to monitor cortical potentials (Electro Encephalogram, or EEG). This data may be subsequently processed in order to determine if a patient is experiencing a seizure, or is at elevated susceptibility to experiencing a seizure. See, e.g., U.S. patent application Ser. No. 12/020,450, “Systems and Methods for Identifying a Contra-ictal Condition in a Subject,” filed Jan. 25, 2008, assigned to the assignee of the present application, the contents of which are hereby incorporated by reference in their entirety.

The design of signal conditioning circuitry for implantable biomedical devices calls for robust and accurate signal sensing capabilities that minimize the effects of external environmental signal sources and the effects of unrelated physiological processes, while effecting minimal disturbance to the patient. A number of different amplification approaches may be used to measure neurological potentials. An often used approach involves measuring the difference in potential between two adjacent electrodes. Because the electrodes are nearby each other, they tend to be affected in the same way by interfering sources such as external static potentials, as interfering signals tend to manifest themselves as common to both channels (“common-mode”). By measuring only the difference in potential between the two electrodes (“differential-mode”), common-mode interference signals may be rejected.

A well-designed system will address factors that prevent common-mode signals from being converted into differential-mode signals (said to be an artifact of the interfering signal), which may be quantified by the “Common Mode Rejection Ratio” or CMRR. Achieving a high CMRR typically requires the use of circuit components with tight tolerances and circuits that embody symmetrical features. While differential measurement approaches tend to provide good rejection of certain types of interfering signals, they also introduce measurement issues. In particular, the ability to resolve the location where a signal is being generated becomes an issue. This is because, in a differential system, it may be unclear as to which of the two electrodes being used in the measurement is sensing the signal.

Other measurement approaches may be used that attempt to measure the signal associated with a single sensing electrode. This is often the case when using implanted sub-dural monitoring electrodes. Use of the signal from a single electrode may help to better localize a region of interest, such as brain tissue that is associated with seizure initiation, i.e., a “seizure onset zone”. The ability to measure the potential associated with a single electrode may also have advantages for use with algorithms such as seizure advisory algorithms. In practice, potentials cannot be measured alone, they must be measured in comparison with another potential. To measure the signal from a single electrode requires the designation of a reference point or reference electrode. A fundamental limitation is that unwanted signal appearing on the reference electrode cannot be distinguished from signal arising on the sensing electrode. For this reason, the reference electrode should be chosen or designed to be as free from signal as possible.

In conventional neuro-amplification systems, a designated reference channel is provided. A user will attempt to place the associated reference electrode in an area that is electrically “quiet”, meaning that the location is largely free from neuro-potentials, myographic potentials, and interfering environmental signals. By its very nature, the reference electrode location tends to be well separated from the area where the desired neuro-potentials are being measured. A typical reference location choice would be the vertex of the patient's head. This location is relatively distant from underlying muscle and associated artifact and tends to exhibit smaller neuro-potential signals. The separation of the reference electrode and the sensing electrodes means that interfering sources may act on the electrodes differently, arising in artifact that is difficult or impossible to remove. When used as part of an implantable system, the separation of the measuring electrodes from the reference electrode could also lead to a need for a more complex system, the need for additional surgical incisions, and increased risk of complications.

### SUMMARY

It would be desirable to create a neuro-amplification system that is able to provide a reasonably quiet reference potential so that signals from single electrodes can be measured in relative isolation. It would also be desirable to minimize the number of electrodes required for the system. This could be accomplished by utilizing all of the electrodes for sensing the signal of interest. Furthermore, it would be desirable to avoid the need for placing a reference electrode at a distant location from other electrodes positioned near the source of the signal of interest.

It would be further desirable to minimize artifact caused by myographic potentials, or by environmental static potentials. It would also be desirable to minimize any residual currents caused by the device as these currents may lead to corrosion issues. Furthermore, it would be desirable to provide techniques for automatically detecting mechanical and/or electrical failure of the sensing device, so that appropriate actions may be taken to address such failure.

In accordance with embodiments of the present invention, an apparatus for amplifying a plurality N of inputs to generate N outputs is provided. The apparatus comprises: a first stage amplifier for amplifying each of the N inputs relative to a first common reference to generate N intermediate outputs, the first common reference comprising the average of the N inputs; and a second stage amplifier for amplifying each of the N intermediate outputs relative to a second common reference to generate the N outputs, the second stage amplifier comprising the average of the N intermediate outputs.

In accordance with embodiments of the present invention, an apparatus for amplifying a plurality N of inputs to generate N outputs is provided, the apparatus comprising: an amplifier for amplifying each of the N inputs relative to a common reference to generate the N outputs, the common reference comprising the average of the N inputs; and a memory coupled to the N outputs, the memory configured to record each of the N outputs.

In accordance with embodiments of the present invention, an apparatus is provided, comprising: a plurality N of electrical input leads; and an amplifier for amplifying voltages at each of the N electrical input leads relative to a common reference to generate N outputs, the common reference comprising the average of the N inputs; wherein each of the N electrical input leads is coupled to a corresponding physiological signal source to be measured.

In accordance with embodiments of the present invention, an apparatus is provided, comprising: a plurality N of electrical input leads; and an amplifier for amplifying voltages at each of the N electrical input leads relative to a common reference to generate N outputs, the common reference comprising the average of the N inputs; wherein none of the N electrical input leads is coupled to a designated reference electrode.

In accordance with embodiments of the present invention, a method is provided comprising: coupling a plurality N of inputs to a physiological signal source; and amplifying the N inputs relative to a common reference to generate N outputs, the common reference comprising the average of the N inputs.

In accordance with embodiments of the present invention, an apparatus for amplifying a plurality N of inputs to generate N outputs is provided, the apparatus comprising: an amplifier for amplifying each of the N inputs relative to a common reference to generate the N outputs, the common reference comprising the average of the N inputs; and a signal processing module configured to process the plurality of output voltages, the signal processing module comprising: a summation module configured to sum the plurality of output voltages; an out-of-range detection module configured to detect when the output of the summation module exceeds a pre-defined range.

In accordance with embodiments of the present invention, a method is provided, comprising: amplifying a plurality N of input voltages using a first stage to generate N first voltages, the amplifying comprising referencing each of the N input voltages to a first common voltage reference, the first common voltage reference comprising the average of the plurality N of input voltages; and amplifying the N first voltages using a second stage to generate N output voltages, the amplifying the N first voltages comprising referencing each of the N first voltages to a second common voltage reference, the second common voltage reference comprising the average of the N first voltages.

In accordance with embodiments of the present invention, an apparatus is provided, comprising: a plurality N of input conducting leads; and amplifier means to amplify the voltages at each of the plurality N of input conducting leads referenced to a common voltage, the common voltage comprising the average of the voltages at the plurality N of input conducting leads.

In accordance with embodiments of the present invention, an apparatus is provided, comprising: a housing; a plurality of input conducting leads; and a plurality of amplifier modules contained in the housing, each amplifier module comprising an input node coupled to a corresponding one of the plurality of input conducting leads, each amplifier module further comprising at least one corresponding output node; wherein a bias node conductively couples a bias voltage to the input node of each amplifier module.

### BRIEF DESCRIPTION OF THE DRAWINGS

FIG. 1 illustrates an exemplary embodiment of an implantable apparatus according to the present disclosure.

FIG. 2 illustrates an exemplary embodiment of the plurality of amplifier modules.

FIG. 3 illustrates an exemplary embodiment of the apparatus wherein input protection circuitry is shown.

FIG. 4 illustrates an alternative exemplary embodiment wherein a clamp is provided in the bias arrangement for additional voltage protection.

FIG. 5 illustrates an alternative exemplary embodiment of the apparatus having impedance measurement capability at the amplifier module inputs.

FIG. 6 illustrates an exemplary embodiment of a calibration voltage generation module.

FIG. 7 illustrates an exemplary embodiment of a method for measuring the impedance between input nodes IN of two amplifier modules using the apparatus of FIG. 5.

FIG. 8 illustrates an exemplary embodiment of a signal processing module configured to generate an anomaly indicator signal.

FIG. 9 illustrates an exemplary embodiment of the present disclosure, wherein insulating sheaths are provided for portions of the conducting leads external to the housing.

FIG. 10 depicts an exemplary embodiment of the present disclosure, wherein the techniques disclosed hereinabove are applied in the context of a real-time patient monitoring and neurological event detection system.

### DETAILED DESCRIPTION

The detailed description set forth below in connection with the appended drawings is intended as a description of exemplary embodiments of the present invention and is not intended to represent the only exemplary embodiments in which the present invention can be practiced. The term “exemplary” used throughout this description means “serving as an example, instance, or illustration,” and should not necessarily be construed as preferred or advantageous over other exemplary embodiments. The detailed description includes specific details for the purpose of providing a thorough understanding of the exemplary embodiments of the invention. It will be apparent to those skilled in the art that the exemplary embodiments of the invention may be practiced without these specific details. In some instances, well known structures and devices are shown in block diagram form in order to avoid obscuring the novelty of the exemplary embodiments presented herein.

In this specification and in the claims, it will be understood that when an element is referred to as being “connected to” or “coupled to” another element, it can be directly connected or coupled to the other element or intervening elements may be present. In contrast, when an element is referred to as being “directly connected to” or “directly coupled to” another element, there are no intervening elements present. When two elements are referred to as being “conductively coupled” to one another, then the two elements are coupled by a path having non-zero conductance, or finite resistance. For example, there may be a short-circuit path (i.e., a path of very high conductance) between two “conductively coupled” elements, or there may be a resistive path between such two “conductively coupled” elements.

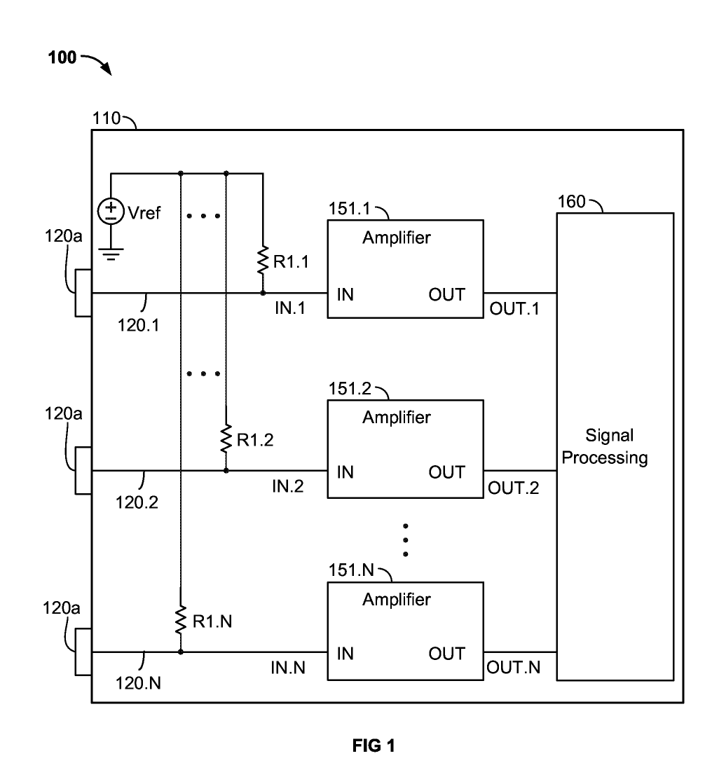

FIG. 1 illustrates an exemplary embodiment of an implantable apparatus 100 according to the present disclosure. Note the apparatus 100 is shown for illustrative purposes only, and is not meant to limit the scope of the present disclosure. In alternative exemplary embodiments, an apparatus may incorporate any or all of the features shown in FIG. 1, and such alternative exemplary embodiments are contemplated to be within the scope of the present disclosure.

In FIG. 1, the apparatus 100 includes a housing or case 110. In an exemplary embodiment, the housing may be made of titanium, ceramic, or other types of biocompatible material, e.g., non-conductive biocompatible materials. The housing is coupled to a plurality of input conducting leads through terminals 120.1 through 120.N. Each input conducting lead may have a portion 120a exposed exterior to the housing 110. Note N denotes herein the number of channels processed by the apparatus, and n will denote an integer index from 1 to N. Each conducting lead 120.n is designed to come in direct physical contact with, e.g., biological tissue or fluid inside the body of a patient, to sense electrical potentials present on such tissue or fluid. Each of the conducting leads 120.n is coupled to a corresponding input node IN.n of a plurality of amplifier modules 151.1 through 151.N.

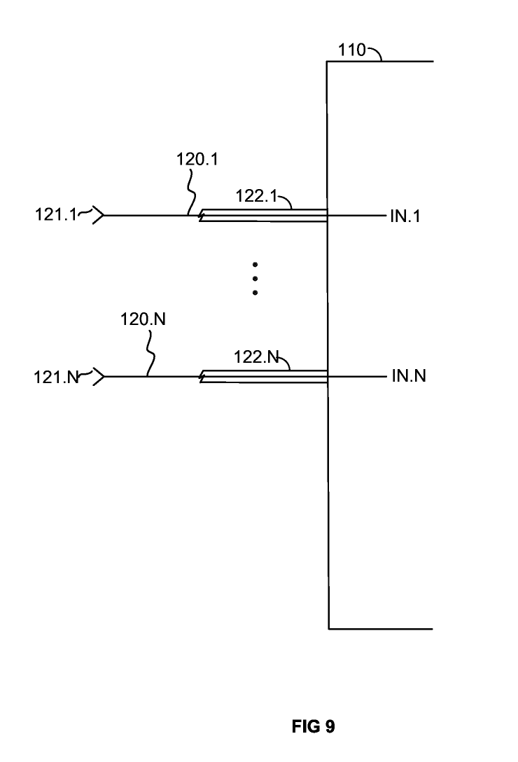

Note the depiction of FIG. 1 is not meant to suggest that the conducting tips of the plurality of input conducting leads or terminals 120.1 through 120.N are necessarily provided directly adjacent the housing. In certain exemplary embodiments, the leads 120.1 through 120.N may extend further exterior to the housing 110, e.g., by incorporating conductive wires of extended length sheathed by an insulating material. Such exemplary embodiments are further described, e.g., with reference to FIG. 9 hereinbelow.

The input to each amplifier module 151.n may be biased by a reference voltage Vref through a corresponding resistor R1.n, also denoted a bias resistance. The amplifier modules 151.1 through 151.N collectively amplify input voltages at IN.1 through IN.N to generate output voltages at OUT.1 through OUT.N, which are provided to a signal processing module 160. The module 160 may perform further signal conditioning on the amplifier module outputs, as well as analog-to-digital conversion for further processing by a digital computational module (not shown).

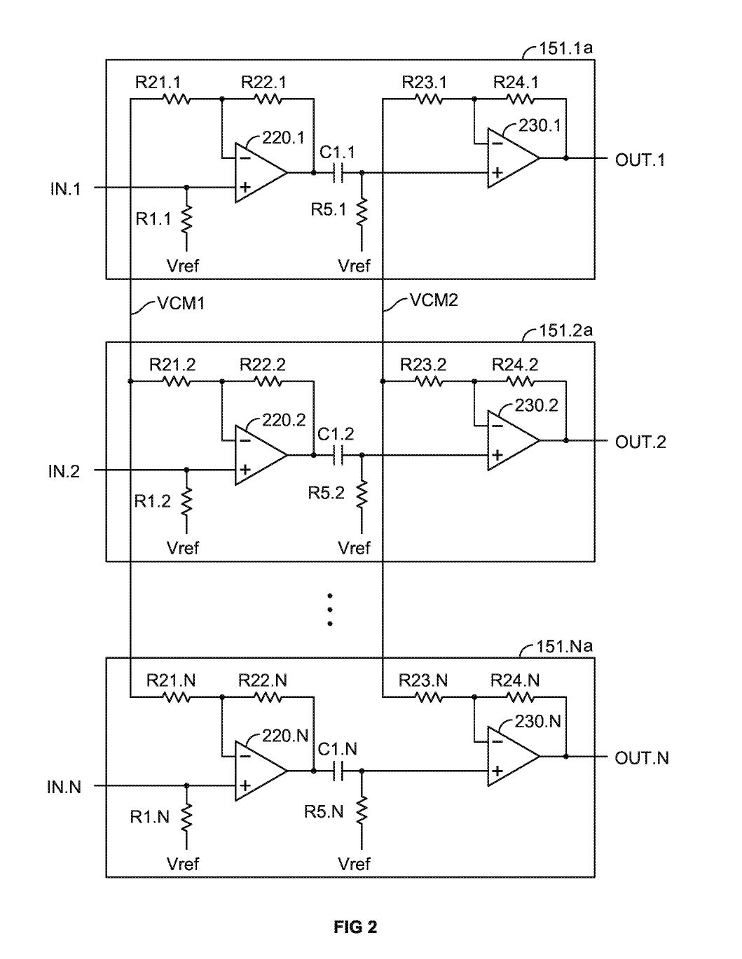

Note the amplifier modules 151.1 through 151.N shown in FIG. 1 may, in some embodiments, be inter-connected with each other using electrical couplings not shown, as later described herein with reference to FIG. 2. The illustration of FIG. 1 is not meant to limit the possible types of inter-connections between amplifier modules.

In accordance with the principles of the present disclosure, the apparatus 100 may amplify and process the plurality of input voltages IN.1 through IN.N without necessarily referencing an independent common voltage, e.g., a ground voltage.

FIG. 2 illustrates an exemplary embodiment of amplifier modules 151.1 through 151.N. Note for ease of illustration, FIG. 2 omits certain details that will be clear to one of ordinary skill in the art, e.g., power supply voltages, additional provision of filtering networks in the circuit, addition or omission of components in the feedback networks of each op amp, etc. Furthermore, FIG. 2 is not intended to limit the implementation of the amplifier modules 151.1 through 151.N in FIG. 1 to that shown in FIG. 2, and one of ordinary skill in the art will appreciate that certain aspects of the present disclosure may readily be applied to alternative implementations of the amplifier modules 151.1 through 151.N.

In FIG. 2, each amplifier module 151.n of FIG. 1 is implemented as a corresponding amplifier module 151.na. For example, amplifier module 151.1a includes a first differential amplifier 220.1 and a second differential amplifier 230.1. In an exemplary embodiment, each of the differential amplifiers 220.1 and 230.1 may be, e.g., an operational amplifier known in the art. In an exemplary embodiment, the non-inverting inputs to each differential amplifier 220.1 and 230.1 may be biased to Vref via resistors R1.1 and R5.1, respectively. It will be appreciated that by biasing all patient-connected conductive leads, e.g., conductive leads 120.1 through 120.N, to a single reference voltage Vref, leakage and/or corrosion in the circuit may be advantageously minimized. In an exemplary embodiment, the bias voltage Vref may be chosen to be at approximately halfway between supply voltages used to power the amplifiers 220 and 230, thereby maximizing the available signal swing at the non-inverting input nodes to both op amps.

In FIG. 2, the non-inverting input of amplifier 220.1 is coupled to the input voltage node IN.1 of amplifier module 151.1. The output of amplifier 220.1 is fed back to its inverting input via the resistive division of resistors 821.1 and 822.1. In alternative exemplary embodiments, it will be appreciated that the resistances R21.1 and 822.1 may be implemented as generalized impedances (e.g., further including reactive elements), and may be denoted herein as the first inverting input impedance and the first feedback impedance, respectively. The output of amplifier 220.1 is further coupled to a coupling capacitor C1.1, which is in turn coupled to the non-inverting input of amplifier 230.1. The output of amplifier 230.1 is similarly fed back to its inverting input via the resistive division of resistors 823.1 and 824.1. In alternative exemplary embodiments, it will be appreciated that the resistances 823.1 and 824.1 may also be implemented as generalized impedances, and may be denoted herein as the second inverting input impedance and the second feedback impedance, respectively. Furthermore, the coupling capacitor C1.1 may also be replaced by a generalized coupling impedance, and may be implemented using passive or active elements. Such alternative exemplary embodiments are contemplated to be within the scope of the present disclosure.

In FIG. 2, each of the amplifier modules 151.1a through 151.Na may be implemented as described hereinabove with reference to amplifier module 151.1a. For example, each amplifier module 151.na may include resistors R21.n and R22.n for feedback of the output of the first differential amplifier 220.n to its inverting input. Note resistors R21.1 through R21.N across all amplifiers 220.1 through 220.N are coupled together at a single common node VCM1. Similarly, resistors 823.1 through R23.N across all amplifiers 230.1 through 230.N are coupled together at a single common node VCM2.

It will be appreciated that the topology shown in FIG. 2 configures each amplifier module 151.n to generate a corresponding output voltage at OUT.n by amplifying the difference between the corresponding input voltage at IN.n and the average of all the input voltages at N.1 through IN.N. The topology thus advantageously provides for the amplification of N input signals to generate N output signals for further processing, advantageously without the need to additionally reference an independent common reference voltage, e.g., a ground voltage. This distinguishes the architecture from other instrumentation amplifiers found in the prior art, wherein one of the N input signals would generally need to be coupled to a “quiet” or otherwise physically separate reference voltage. Furthermore, prior art instrumentation amplifiers are generally not capable of providing N output voltages for N input voltages, unless a separate voltage, e.g., a ground voltage, is also referenced at the input and/or the output.

By eliminating the need to provide a physically separate reference voltage, as earlier described in the Background section, the amplifier architecture of FIG. 2 further advantageously simplifies the design of the sensing system, and further eliminates the potential need for additional surgical incisions, and increased risk of complications. Furthermore, it will be appreciated that the architecture of FIG. 2 provides improved common-mode rejection, compared to prior art amplifiers that require a separate reference voltage.

Note the configuration of amplifiers 220.1 through 220.N, along with feedback networks, may be referred to as a composite “first-stage amplifier” in the present disclosure, and in the claims. Similarly, amplifiers 230.1 through 230.N, along with feedback networks, may be referred to as a composite “second-stage amplifier.”

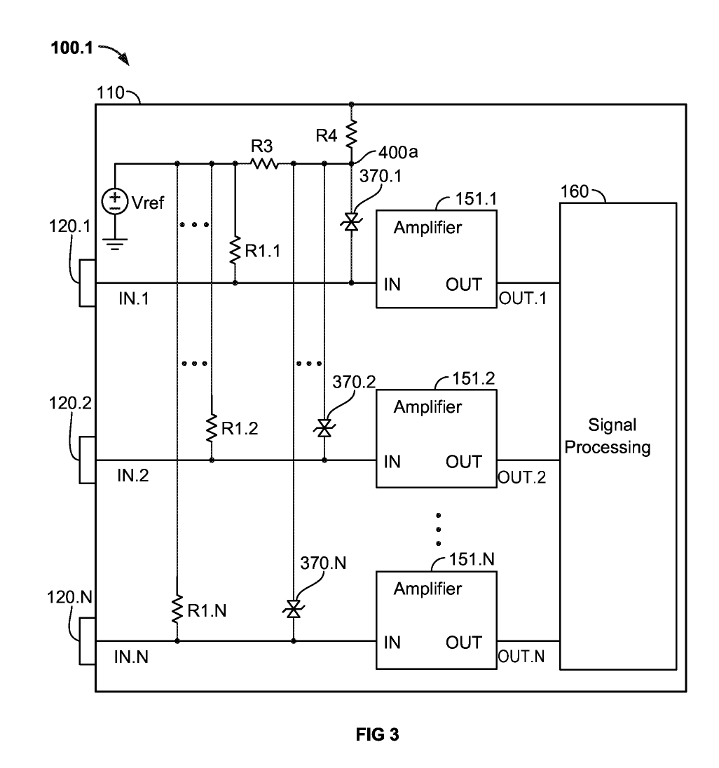

In an aspect of the present disclosure, input protection circuitry is further provided to the apparatus 100 to protect against possible adverse electrical events. FIG. 3 illustrates an exemplary embodiment 100.1 of the apparatus 100 wherein input protection circuitry is shown. In FIG. 3, one end of a bidirectional Zener diode 370.1 is coupled to the input node IN.1 of amplifier 151.1, while another end of the diode 370.1 is coupled to a node 400a. Similarly, diodes 370.2 through 370.N are provided for amplifier modules 151.2 through 151.N. Note all diodes 370.1 through 370.N share the common node 400a.

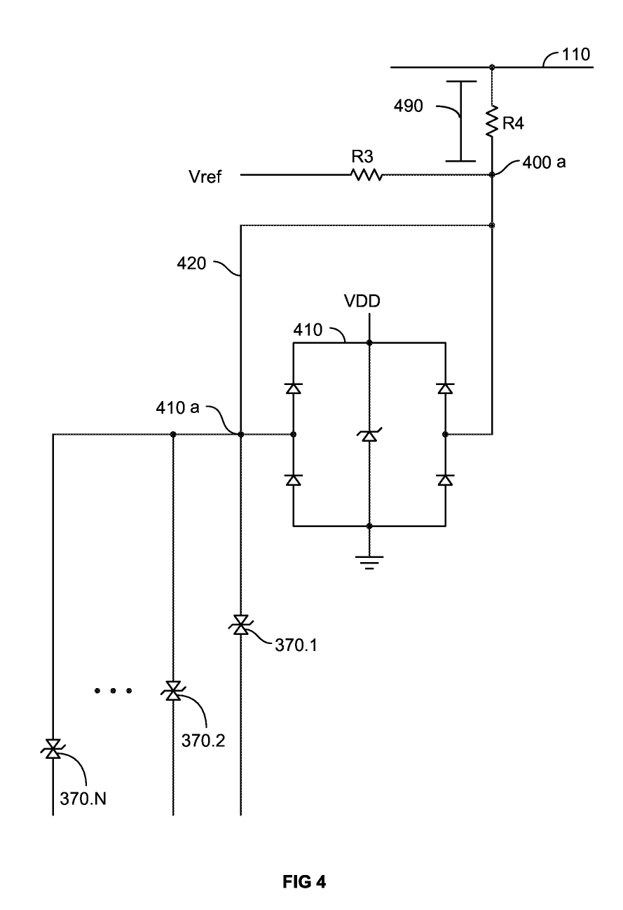

It will be appreciated that the diodes 370.1 through 370.N may function to prevent excessive voltage from being built up between any of inputs IN.1 through IN.N. Note the connection of node 400a to Vref through resistor R3 keeps corresponding input nodes IN.1 through IN.N biased within the range of the input protection devices 410 later described herein with reference to FIG. 4. The connection of node 400a to Vref further minimizes the voltages across diodes 370.1 through 370.N and hence leakage through them, thereby also reducing unwanted noise generation. One of ordinary skill in the art will appreciate that in alternative exemplary embodiments, other devices may be used in place of the bidirectional Zener diodes shown, e.g., unidirectional Zener diodes, other clamping devices known in the art, etc.

Further shown in FIG. 3 is a resistor R4 coupling node 400a to the housing 110. It will be appreciated that such a configuration may advantageously minimize potential differences amongst the internal bias of amplifier modules 151.1 through 151.N, the housing 110, and the conducting leads 120.1 through 120.N. In an exemplary embodiment, all components (including the housing 110) that are in contact with the patient may be coupled to the same reference voltage. In an exemplary embodiment, R4 may have a suitably high resistance, e.g., 1 Gigaohm, to maximize resistance from Vref to the housing, thereby minimizing current flow and maintaining high common-mode rejection ratio (CMRR). Further note the provision of R4 may advantageously prevent static build-up when the apparatus is disposed outside of the human body, and also limit leakage current between two components in contact with the patient, e.g., the housing and a lead contact.

Note in alternative exemplary embodiments, other resistive networks (not shown) may be provided in place of, or in addition to, R3 and R4 shown in FIG. 3 to accomplish functions similar to those described. For example, parallel paths and/or multiple resistors may be provided between any of the housing 110, Vref, and the nodes IN.1 through IN.N, to offer more conductive paths. Such alternative exemplary embodiments are contemplated to be within the scope of the present disclosure.

FIG. 4 illustrates an alternative exemplary embodiment wherein a clamp 410 is provided in the bias arrangement for additional voltage protection. In FIG. 4, the outputs of the diodes 370.1 through 370.N are jointly coupled to a node 410a, while a clamp 410 clamps nodes 410a and 400a to a range between VDD and GND. In the illustrated embodiment, clamp 410 includes two inputs. Nodes 400a and 410a are coupled together via path 420 and to each of the two inputs on claim 410, respectively. Alternatively, a clamp 410 having a single input coupled to both node 400a and 410a could be used. It will be appreciated that the clamp 410 may shunt excess current at the input nodes IN.1 through IN.N to the supply voltage VDD or to ground through the diodes depicted in the clamp 410. As a result, the input nodes IN.1 through INN can be clamped to a desired safe range.

In an exemplary embodiment, for further protection against large voltages accumulating between the housing 110 and any other circuit element, an air gap may be provided between the housing 110 and any reference voltage or any circuit element protected against static discharge, e.g. any of the Zener diodes shown in FIG. 4. In FIG. 4, an exemplary air gap 490 is shown between the housing 110 and the node 400a. It will be appreciated that other air gaps not shown in FIG. 4 may also be provided in the device according to the principles described herein, and such alternative exemplary embodiments are contemplated to be within the scope of the present disclosure.

The air gap 490 may be implemented by limiting the physical separation between the housing 110 and the node 400a to be less than a maximum distance, e.g., 1 millimeter. The air gap 490 thus effectively acts as a parallel path to the resistance R4 to discharge any large voltage potentials between the housing 110 and the node 400a through electrical arcing resulting from breakdown of a gas medium, e.g., helium, between the housing 110 and the node 400a.

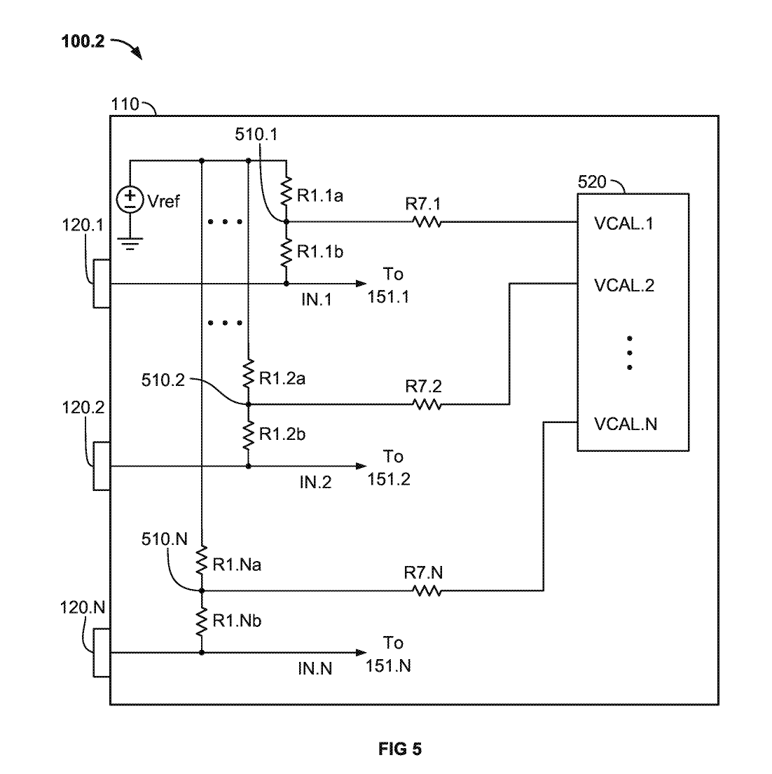

In a further aspect of the present disclosure, input impedance measurement capability is provided for the apparatus 100. FIG. 5 illustrates an alternative exemplary embodiment 100.2 of the apparatus 100 having impedance measurement capability at the amplifier module inputs. In FIG. 5, the resistance R1.n biasing the input IN.n to each amplifier module is split into two component series resistances R1.na and R1.nb. For example, the resistance R1.1 coupling the reference voltage Vref to IN.1 is tapped at an internal node 510.1, thereby splitting the resistance R1.1 into two resistances R1.1a and R1.1b. Each internal node 510.n, also denoted the calibration node, may be further coupled via a resistance R7.n to a corresponding calibration voltage VCAL.n generated by a calibration module 520. In an exemplary embodiment, the module 520 may generate VCAL.n using a programmable voltage source, e.g., as an output of a digital-to-analog converter on a microprocessor (not shown), or as selected from amongst a plurality of input voltages to a multiplexer. In another embodiment, the module 520 generates VCAL.n using standard digital outputs, e.g., from a microprocessor switching between the microprocessor's low and high digital voltages, utilizing the resistances R7.n and R1.na to attenuate the microprocessor's output voltages VCAL.n to the desired level. By utilizing the microprocessor's standard low and high digital voltages to generate VCAL.n, it is possible to avoid the need to manage additional digital-to-analog converters. Each calibration voltage VCAL.n may include, e.g., DC (static) or AC (time-varying) waveforms.

In an exemplary embodiment, measurement of the impedance between any two input nodes IN.x and IN.y, wherein x and y (≠x) are each an integer index from 1 to N, may proceed as described hereinbelow. In an illustrative case wherein x=1 and y=2, a first voltage VCAL.1 may be coupled to the node 510.1 via resistor R7.1, while a second voltage VCAL.2 (≠VCAL.1) may be coupled to the node 510.2 via resistor R7.2. By measuring the voltage difference between nodes IN.1 and IN.2 using amplifiers 151.1 and 151.2, an indication of the impedance between the nodes 510.1 and 510.2 may be derived.

It will be appreciated that by appropriately setting the calibration voltages VCAL.x and VCAL.y, and accounting for the parallel- and series-coupled intermediate resistances, an indication of the impedance between any two input nodes IN.x and IN.y may be obtained. In an exemplary embodiment, the calibration voltage generation module 520 may be, e.g., a microprocessor having N separate DAC outputs that can generate programmable voltage levels. In an exemplary embodiment, the calibration voltage generation module 520 may further be provided with current measurement capability to measure the current flowing through each voltage source VCAL.1 through VCAL.N.

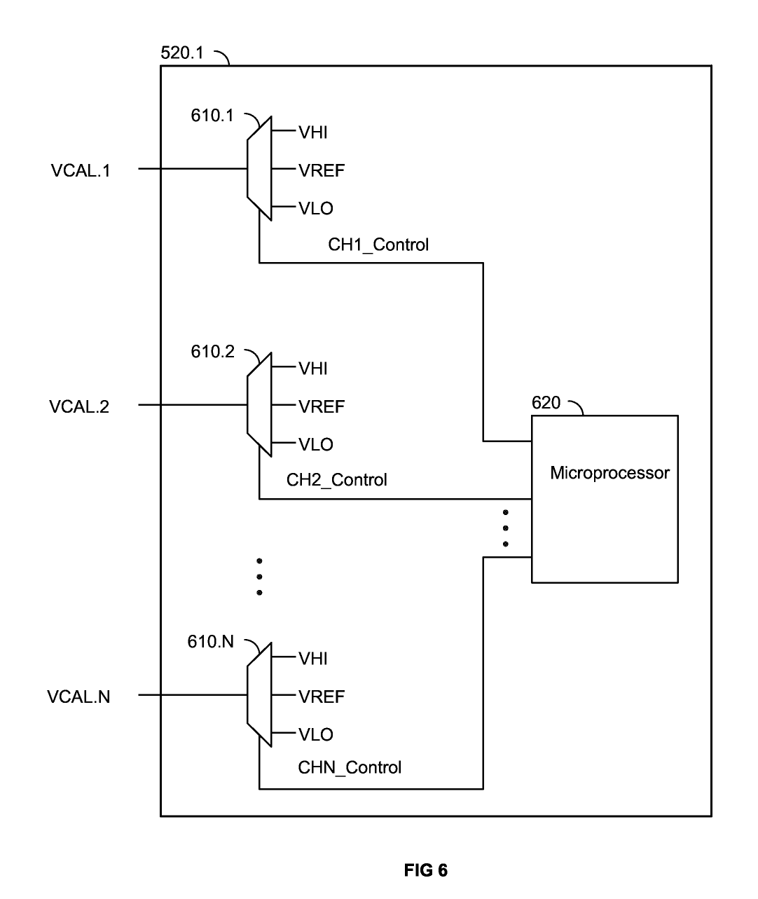

FIG. 6 illustrates an exemplary embodiment 520.1 of a calibration voltage generation module 520. Note the voltage generation module 520.1 is shown for illustrative purposes only, and is not meant to limit the scope of the present disclosure to any particular voltage generation module shown. Furthermore, it will be appreciated that certain details of the circuits described hereinabove are omitted from FIG. 6 for ease of illustration.

In FIG. 6, each calibration voltage VCAL.n is generated by a corresponding multiplexer 610.n programmed to select the value of VCAL.n from amongst a plurality of inputs including Vref, a voltage VHI higher than Vref, and a voltage VLO lower than Vref. A control signal CHn_CONTROL is provided to each multiplexer 610.n to select the calibration voltage VCAL.n from amongst Vref, VHI, and VLO. In an exemplary embodiment, the impedance between the nodes IN of any two amplifier modules 151.x and 151.y, wherein x and y are integer indices from 1 to N not equal to each other, may be measured by programming the microprocessor 620 to generate suitable differential voltages VCAL.x and VCAL.y at the corresponding calibration nodes 510.n of the amplifier modules using CHn_CONTROL.

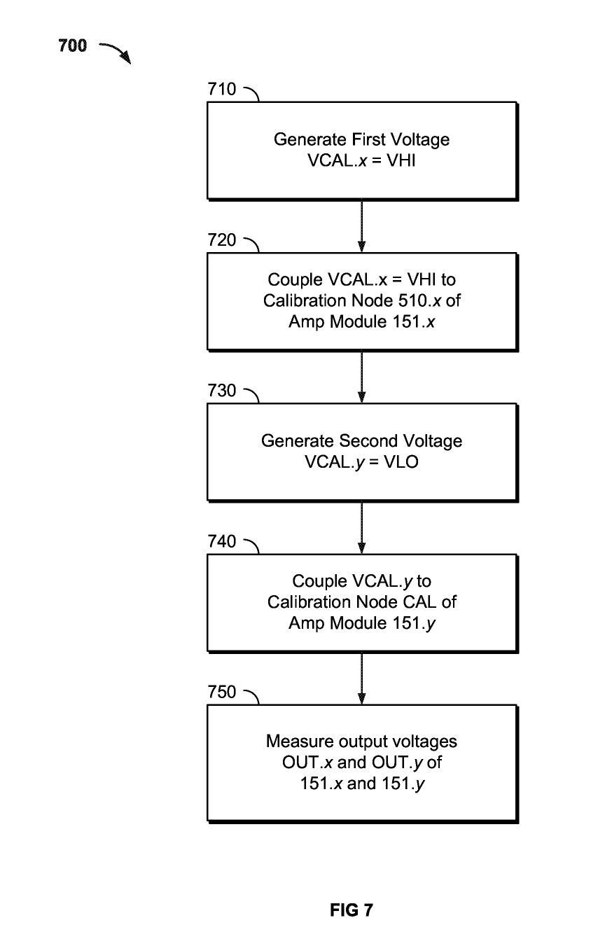

FIG. 7 illustrates an exemplary embodiment 700 of a method for measuring the impedance between input nodes IN of two amplifier modules using the apparatus 100.2 of FIG. 5. Note the method 700 is shown for illustrative purposes only, and is not meant to limit the scope of the present disclosure to any particular method shown.

In FIG. 7, at block 710, a first voltage VCAL.x=VHI is generated by the calibration voltage generation module 520. In an exemplary embodiment, the calibration voltage generation module 520 may be implemented as embodiment 520.1 shown in FIG. 6, and the setting of VCAL.x may be performed by utilizing a multiplexer as shown in FIG. 6.

At block 720, the first voltage VCAL.x is coupled to the calibration node CAL of a first amplifier module 151.x.

At block 730, a second voltage VCAL.y=VLO is further generated by the calibration voltage generation module 520.

At block 740, the second voltage VCAL.y is coupled to the calibration node CAL of a second amplifier module 151.y.

At block 750, the output voltages OUT.x and OUT.y of amplifier modules 151.x and 151.y are measured to determine a voltage drop across IN.x and IN.y, which also provides an indication of the impedance between IN.x and IN.y.

In an exemplary embodiment, by calculating the impedance present between the IN nodes of any two amplifier modules in the apparatus 100.2, i.e., the electrode contact impedance, mechanical or electrical failures resulting in, e.g., a short circuit between the inputs of any two amplifier modules may be detected. Furthermore, if the apparatus 100.2 including terminals 120.1 through 120.N is implanted in a patient body, and placed in contact with, e.g., body tissue or fluid, then, in the absence of any short circuit failures in the device, the measured electrode contact impedance between two terminals may represent the signal source impedance of the body tissue or fluid. Data on the signal source impedance may be utilized by, e.g., the signal processing module 160, to more accurately process the voltage outputs of the amplifier modules, according to techniques derivable by one of ordinary skill in the art.

In a further aspect of the present disclosure, techniques are provided to identify mechanical and/or electrical anomalies when multiple amplifier modules are configured to amplify the difference between their corresponding inputs and the average of all amplifier module inputs. In an exemplary embodiment, each amplifier module output OUT.n is configured to be proportional (over the pass-band of the amplifier module) to the difference between the corresponding amplifier module input IN.n and the average of all amplifier module inputs IN.1 through IN.N. Due to the property that each amplifiers 151.n is configured to amplify the difference between the corresponding input voltage IN.n and the average of all input voltages, as described with reference to FIG. 2, it is expected that the instantaneous sum of all amplifier module outputs OUT.1 through OUT.N will be equal to zero or to a constant reference voltage VA during normal operation. By computing the sum of the amplifier module outputs, and determining whether the sum deviates significantly from zero, or VA, anomalies in the amplifier module operation, e.g., mechanical and/or electrical anomalies, may be identified.

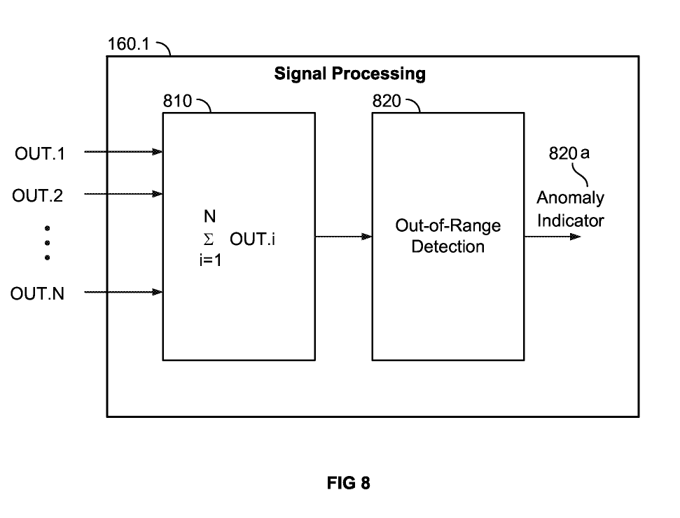

FIG. 8 illustrates an exemplary embodiment 160.1 of a signal processing module 160 configured to generate an anomaly indicator signal. In FIG. 8, the amplifier module outputs OUT.1 through OUT.N are provided to the summation module 810, which computes the sum of all amplifier module outputs at a given time. Note the amplifier module outputs OUT.1 through OUT.N may be generated, e.g., according to the cross-coupled amplifier module configuration shown in FIG. 2. The output of the summation module 810 is provided to an out-of-range detection module 820. The module 820 may be configured to determine when the sum of the amplifier module outputs exceeds a given positive threshold, or is less than a negative threshold, and generate an anomaly indicator signal 820a indicating when the sum is out of the acceptable range. The anomaly indicator signal 820a may be used, e.g., as a diagnostic indicator to signal when a possible mechanical or electrical failure is present in the circuit. For example, the presence of an AC signal (e.g. 60 Hz) on this sum may indicate that a large common-mode AC signal is present at the inputs to the amplifier.

FIG. 9 illustrates an exemplary embodiment of the present disclosure, wherein insulating sheaths are provided for portions of the conducting leads external to the housing. In FIG. 9, each of the conducting leads 120.1 through 120.N is provided with a corresponding insulating sheath 122.1 through 122.N, respectively, for shielding portions of the conducting leads extending in length beyond the housing 110. The leads 120.1 through 120.N are exposed at their tips 121.1 through 121.N, respectively, to enable the lead tips to sense electrical potentials. The tips 121.1 through 121.N may include, e.g., electrodes configured to optimally contact tissue or other body surfaces. Note a base insulating sheath (not shown) may be further provided to bundle the plurality of insulating sheaths 122.1 through 122.N proximal to their origin at the housing 110.

In an exemplary embodiment, the plurality of conductive leads 120.1 through 120.N, along with corresponding insulating sheaths 122.1 through 122.N, not shown in FIG. 9) may be bundled in a single base insulating sheath and provided as, e.g., a flexible cable having electrodes extending therefrom. The cable may have a proximal end connector (not shown) that is detachably couplable to a corresponding connector interface (not shown) provided on the housing 110. In alternative exemplary embodiments, the single cable need not be detachably couplable to the housing 110, and may be configured to remain fixed to the housing 110.

In exemplary embodiments, the conducting leads may be simultaneously or alternatively configured as described in co-pending U.S. patent application Ser. No. 12/020,507, entitled “Methods and Systems for Measuring a Subject's Susceptibility to a Seizure,” filed Jan. 25, 2008; U.S. patent application Ser. No. 12/630,300, entitled “Universal Electrode Array for Monitoring Brain Activity,” filed Dec. 3, 2009; and U.S. patent application Ser. No. 12/685,543, filed Jan. 11, 2010, entitled “Medical Lead Termination Sleeve for Implantable Medical Devices,” all of which are assigned to the assignee of the present disclosure, the contents of which are hereby incorporated in their entireties.

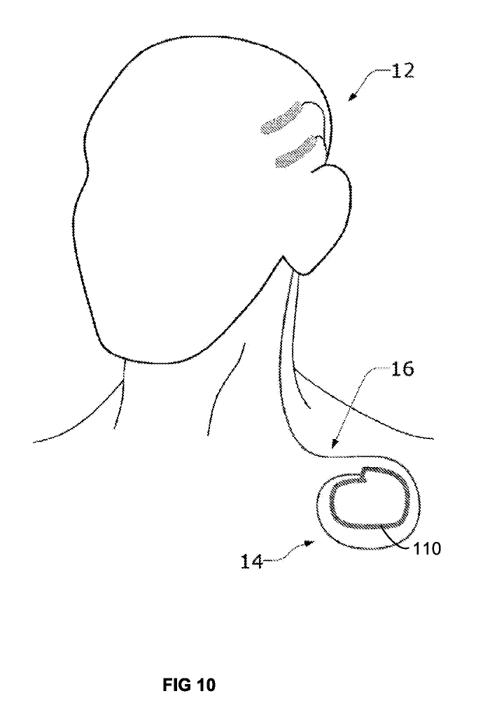

FIG. 10 depicts an exemplary embodiment of the present disclosure, wherein the techniques disclosed hereinabove are applied in the context of a real-time patient monitoring and neurological event detection system. Note that FIG. 10 is provided for illustrative purposes only, and is not meant to limit the application of the amplifier techniques described herein to any particular biomedical applications. For a more detailed description of the system in FIG. 9, see, e.g., “Minimally Invasive Monitoring Methods,” U.S. patent application Ser. No. 11/766,751, filed Jun. 21, 2007, assigned to the assignee of the present application, the contents of which are hereby incorporated by reference in their entirety.

In an exemplary embodiment, as shown in FIG. 10, the plurality of insulated conducting leads 120.1 through 120.N may be provided as an electrode array 12. The electrode array 12 is connected to the housing 110 of an implanted assembly 14 via the wire leads 16. The conducting leads may be bundled in a single cable 16, and the cable 16 may be tunneled between the cranium and the scalp and subcutaneously through the neck to the implanted assembly 14. Typically, implanted assembly 14 may be implanted in a sub-clavicular pocket in the subject, but the implanted assembly 14 may be disposed somewhere else in the subject's body. For example, the implanted assembly 14 may be implanted in the abdomen or underneath, above, or within an opening in the subject's cranium (not shown).

In FIG. 10, the electrode array 12 may be positioned anywhere in, on, and/or around the subject's brain, but typically one or more of the electrodes are implanted within in the subject. For example, one of more of the electrodes may be implanted adjacent or above a previously identified epileptic network, epileptic focus or a portion of the brain where the focus is believed to be located. While not shown, it may be desirable to position one or more electrodes in a contralateral position relative to the focus or in other portions of the subject's body to monitor other physiological signals.

The electrode arrays 12 of the present invention may be intracranial electrodes (e.g., epidural, subdural, and/or depth electrodes), extracranial electrodes (e.g., spike or bone screw electrodes, subcutaneous electrodes, scalp electrodes, dense array electrodes), or a combination thereof. While it is preferred to monitor signals directly from the brain, it may also be desirable to monitor brain activity using sphlenoidal electrodes, foramen ovale electrodes, intravascular electrodes, peripheral nerve electrodes, cranial nerve electrodes, or the like. While the remaining disclosure focuses on intracranial electrodes for sampling intracranial EEG, it should be appreciated that the present invention encompasses any type of electrodes that may be used to sample any type of physiological signal from the subject. It will be appreciated that the electrical potentials as sampled by the electrode arrays 12 may be coupled to input conductive leads and processed according to the techniques described in the present disclosure. In an aspect, the neural signals of the patient are sampled substantially continuously with the electrodes coupled to the electronic components of the implanted leadless device. In particular, electrical signal amplification and sampling may be performed by an apparatus such as that described hereinabove with reference to, e.g., FIGS. 1-9, with the number of electrodes corresponding to the number N of conducting leads and amplifier modules provided.

In the configuration illustrated in FIG. 10, two electrode arrays 12 are positioned in an epidural or subdural space, but as noted above, any type of electrode placement may be used to monitor brain activity of the subject. For example, in a minimally invasive embodiment, the electrode array 12 may be implanted between the skull and any of the layers of the scalp. Specifically, the electrodes 12 may be positioned between the skin and the connective tissue, between the connective tissue and the epicranial aponeurosis/galea aponeurotica, between the epicranial aponeurosis/galea aponeurotica and the loose aerolar tissue, between the loose aerolar tissue and the pericranium, and/or between the pericranium and the calvarium. To improve signal-to-noise ratio, such subcutaneous electrodes may be rounded to conform to the curvature of the outer surface of the cranium, and may further include a protuberance that is directed inwardly toward the cranium to improve sampling of the brain activity signals. Furthermore, if desired, the electrode may be partially or fully positioned in openings disposed in the skull. Additional details of exemplary wireless minimally invasive implantable devices and their methods of implantation can be found in U.S. patent application Ser. No. 11/766,742, entitled “Minimally Invasive Monitoring Systems,” filed Jun. 21, 2007, the disclosure of which is incorporated by reference herein in its entirety.

In an exemplary embodiment, the implanted assembly 14 may include software to pre-process the data according to the present disclosure and analyze the data in substantially real-time. For example, the sampled EEG from the electrode arrays 12 may be analyzed for the presence of anomalies according to the present disclosure, and further by EEG analysis algorithms to estimate the patient's brain state which is typically indicative of the patient's propensity for a neurological event. The neurological event may be a seizure, migraine headache, episode of depression, tremor, or the like. The estimation of the patient's brain state may cause generation of an output. The output may be in the form of a control signal to activate a therapeutic device (e.g., implanted in the patient, such as a vagus nerve stimulator, deep brain or cortical stimulator, implanted drug pump, etc.).

In an exemplary embodiment, the implanted assembly 14 may further wirelessly communicate with an external device (not shown) to activate a user interface and produce an output communication to the patient. For example, the external device may be used to provide a substantially continuous output or periodic output communication to the patient that indicates their brain state and/or propensity for the neurological event. Such a communication could allow the patient to manually initiate self-therapy (e.g., wave wand over implanted vagus nerve stimulator, cortical, or deep brain stimulator, take a fast acting anti-epileptic drug, etc.).

In an alternative exemplary embodiment, the external device may further communicate with an auxiliary server (not shown) having more extensive computational and storage resources than can be supported in the form factor of the external device. In such an exemplary embodiment, anomaly pre-processing and EEG analysis algorithms may be performed by an auxiliary server, or the computations of the external device may be otherwise facilitated by the computational resources of the auxiliary server.

Based on the teachings described herein, it should be apparent that an aspect disclosed herein may be implemented independently of any other aspects and that two or more of these aspects may be combined in various ways. In one or more exemplary embodiments, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD/DVD-ROM or other optical disk storage, magnetic disk storage or other magnetic storage devices, solid-state flash cards or drives, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-Ray disc where disks usually reproduce data magnetically, while discs reproduce data optically with lasers. Combinations of the above should also be included within the scope of computer-readable media.

A number of aspects and examples have been described. However, various modifications to these examples are possible, and the principles presented herein may be applied to other aspects as well. These and other aspects are within the scope of the following claims.

What is claimed is:

1. An apparatus for amplifying a plurality N of inputs to generate N outputs, the apparatus comprising:
a first stage amplifier for amplifying each of the N inputs relative to a first common reference to generate N intermediate outputs, the first common reference comprising the average of the N inputs; and
a second stage amplifier for amplifying each of the N intermediate outputs relative to a second common reference to generate the N outputs, the second stage amplifier comprising the average of the N intermediate outputs.

2. The apparatus of claim 1, further comprising AC coupling capacitors coupling each of the N intermediate outputs to the second stage amplifier.

3. The apparatus of claim 1, further comprising a memory coupled to the N outputs of the apparatus, the memory configured to record each of the N outputs.

4. The apparatus of claim 1, each of the first and second stage amplifiers comprising N differential amplifiers, each differential amplifier comprising a non-inverting input, an inverting input, and an output, wherein:
the non-inverting input of each differential amplifier is coupled to a corresponding one of the plurality of inputs;
the non-inverting input of each differential amplifier is coupled to the output of the differential amplifier via a coupling impedance;
the output of each differential amplifier is coupled to the inverting input of the differential amplifier via a first feedback impedance; and
the inverting input of the differential input is further coupled to a first common node via an inverting input impedance.

5. An apparatus for amplifying a plurality N of inputs to generate N outputs, the apparatus comprising:
an amplifier for amplifying each of the N inputs relative to a common reference to generate the N outputs, the common reference comprising the average of the N inputs; and
a memory coupled to the N outputs, the memory configured to record each of the N outputs.

6. An apparatus comprising:
a plurality N of electrical input leads; and
an amplifier for amplifying voltages at each of the N electrical input leads relative to a common reference to generate N outputs, the common reference comprising the average of the N inputs;
wherein each of the N electrical input leads is coupled to a corresponding physiological signal source to be measured.

7. The apparatus of claim 6, wherein the physiological signal sources comprise brain tissue.

8. An apparatus comprising:
a plurality N of electrical input leads; and
an amplifier for amplifying voltages at each of the N electrical input leads relative to a common reference to generate N outputs, the common reference comprising the average of the N inputs;
wherein none of the N electrical input leads is coupled to a designated reference electrode.

9. A method comprising:
coupling a plurality N of inputs to a physiological signal source; and
amplifying the N inputs relative to a common reference to generate N outputs, the common reference comprising the average of the N inputs.

10. The method of claim 9, wherein none of the N inputs are coupled to a designated reference electrode.

11. An apparatus for amplifying a plurality N of inputs to generate N outputs, the apparatus comprising:
an amplifier for amplifying each of the N inputs relative to a common reference to generate the N outputs, the common reference comprising the average of the N inputs; and
a signal processing module configured to process the plurality of output voltages, the signal processing module comprising:
a summation module configured to sum the plurality of output voltages;
an out-of-range detection module configured to detect when the output of the summation module exceeds a pre-defined range.

12. A method comprising:
amplifying a plurality N of input voltages using a first stage to generate N first voltages, the amplifying comprising referencing each of the N input voltages to a first common voltage reference, the first common voltage reference comprising the average of the plurality N of input voltages; and
amplifying the N first voltages using a second stage to generate N output voltages, the amplifying the N first voltages comprising referencing each of the N first voltages to a second common voltage reference, the second common voltage reference comprising the average of the N first voltages.

13. An apparatus comprising:
a plurality N of input conducting leads; and
amplifier means to amplify the voltages at each of the plurality N of input conducting leads referenced to a common voltage, the common voltage comprising the average of the voltages at the plurality N of input conducting leads.

14. An apparatus comprising:
a housing;
a plurality of input conducting leads; and
a plurality of amplifier modules contained in the housing, each amplifier module comprising an input node coupled to a corresponding one of the plurality of input conducting leads, each amplifier module further comprising at least one corresponding output node;
wherein a bias node conductively couples a bias voltage to the input node of each amplifier module.

15. The apparatus of claim 14, further comprising:
an insulating sheath insulating each of the plurality of input conducting leads for a portion of said lead exterior to the housing.

16. The apparatus of claim 15, further comprising:
a base insulating sheath bundling the plurality of insulating sheaths for a portion of the insulating sheaths adjacent to the housing.

17. The apparatus of claim 16, the base insulating sheath, plurality of insulating sheath, and a portion of each of the plurality of input conducting leads being provided in a cable.

18. The apparatus of claim 17, said cable having a connector that is detachably couplable to a connector interface on the housing.

19. The apparatus of claim 14, each amplifier module comprising a first differential amplifier, the bias voltage coupled to the non-inverting input of the first differential amplifier of each amplifier module.

20. The apparatus of claim 19, each amplifier module further comprising a second differential amplifier, the bias voltage further coupled to the non-inverting input of the second differential amplifier of each amplifier module.

21. The apparatus of claim 20, the bias voltage further conductively coupled to the housing.

22. The apparatus of claim 21, the housing conductively coupled to the bias voltage through a resistance.

23. The apparatus of claim 22, the housing separated from a node conductively coupled to the reference bias voltage by no more than an air gap separation distance.

24. The apparatus of claim 23, the air gap separation distance being 1 millimeter, wherein the housing is hermetically sealed and contains helium gas.

25. The apparatus of claim 21, the bias voltage further coupled to at least one of the plurality of input conducting leads through a corresponding clamp diode.

26. The apparatus of claim 25, the housing separated from a node conductively coupled to at least one clamp diode by no more than an air gap separation distance.

27. The apparatus of claim 14, the amplifier module further comprising means for determining an impedance between two of the plurality of input conducting leads.

28. The apparatus of claim 27, each amplifier module further comprising a bias resistance coupling the bias voltage to each input conducting lead, each bias resistance being tapped at a calibration node, the apparatus further comprising a calibration voltage generation module configured to generate a calibration voltage coupled to each calibration node.

29. The apparatus of claim 27, further comprising a signal processing module configured to process the plurality of output voltages, wherein the signal processing module is configured to determine the impedance between two of the input conducting leads by measuring the two output voltages corresponding to said two of the input conducting leads.

30. The apparatus of claim 28, the calibration voltage generation module further configured to generate each calibration voltage by selecting from amongst at least three input voltages comprising a voltage higher than the bias voltage, a voltage lower than the bias voltage, and the bias voltage.

31. The apparatus of claim 14, the coupling impedance comprising an active capacitance network.
